(19) United States
(12) Patent Application Publication
(10) Pub. No.: US 2025/0072034 A1
(43) Pub. Date: Feb. 27, 2025

(54) NITRIDE SEMICONDUCTOR DEVICE AND MANUFACTURING METHOD THEREOF

(71) Applicant: ROHM CO., LTD., Kyoto-shi (JP)

(72) Inventor: Yosuke HATA, Kyoto-shi (JP)

(73) Assignee: ROHM CO., LTD., Kyoto-shi (JP)

(21) Appl. No.: 18/798,916

(22) Filed: Aug. 9, 2024

(30) Foreign Application Priority Data
Aug. 21, 2023 (JP) 2023-133783

(51) Int. Cl. H01L 29/778; H01L 29/20; H01L 29/417; H01L 29/66

(52) U.S. Cl. CPC H01L 29/7787; H01L 29/2003; H01L 29/41775; H01L 29/66462

(57) ABSTRACT

The present disclosure provides a nitride semiconductor device. The nitride semiconductor device includes: an electron travelling layer; an electron supply layer; a gate layer, formed on the electron supply layer; a gate electrode, formed on the gate layer; and a passivation layer, having a source opening and a drain opening. The electron travelling layer includes: a first portion, located under the gate layer; and a second portion, located between the gate layer and the source opening, and located between the gate layer and the drain opening. The electron supply layer includes: a first electron supply layer, formed on the first portion and located below the gate layer; and a second electron supply layer, formed on the second portion and connected to the first electron supply layer.

### CROSS-REFERENCE TO RELATED APPLICATION

This application is based upon and claims the benefit of priority from Japanese Patent Application No. 2023-133783, filed on Aug. 21, 2023, the entire contents of which are incorporated herein by reference.

### TECHNICAL FIELD

The present disclosure relates to a nitride semiconductor device and a manufacturing method thereof.

### BACKGROUND

Currently, the manufacturing of high electron mobility transistors (HEMT) using group III nitride semiconductors such as gallium nitride (GaN) (hereinafter sometimes referred to as “nitride semiconductors”) is in progress. In a HEMT, a two-dimensional electron gas (2DEG) formed near a semiconductor heterojunction interface is used a conductive path (channel). A power device utilizing a HEMT is considered a device having a lower on resistance and operable at a higher speed and a higher frequency than a typical silicon (Si) power device.

For example, a nitride semiconductor device described in patent document 1 includes an electron travelling layer made of a GaN layer, and an electron supply layer made of an aluminum gallium nitride (AlGaN) layer. The 2DEG is formed in the electron travelling layer near a heterojunction interface between the electron travelling layer and the electron supply layer.

Moreover, in the nitride semiconductor device of patent document 1, a gate layer (for example, a p-type GaN layer) containing acceptor-type impurities is provided on the electron supply layer, and a gate electrode is arranged on the gate layer. In the configuration above, in a region directly below the gate layer, the band energy of a conduction band near the heterojunction interface between the electron travelling layer and the electron supply layer is increased through the gate layer, such that a channel directly below the gate layer disappears and a condition of normally off is incurred.

### PRIOR ART DOCUMENT

### Patent Publication

[Patent document 1] Japan Patent Publication No. 2017-73506

### BRIEF DESCRIPTION OF THE DRAWINGS

FIG. 1 is a schematic plan view of an exemplary nitride semiconductor device according to an embodiment.

FIG. 2 is a cross-sectional diagram taken along the line 2-2 in FIG. 1.

FIG. 3 is an enlarged cross-sectional diagram of a structure around a gate layer as an example.

FIG. 4 is a schematic cross-sectional diagram of an exemplary manufacturing step of a nitride semiconductor device according to an embodiment.

FIG. 5 is a schematic cross-sectional diagram of a manufacturing step following the step shown in FIG. 4.

FIG. 6 is a schematic cross-sectional diagram of a manufacturing step following the step shown in FIG. 5.

FIG. 7 is a schematic cross-sectional diagram of a manufacturing step following the step shown in FIG. 6.

FIG. 8 is a schematic cross-sectional diagram of a manufacturing step following the step shown in FIG. 7.

FIG. 9 is a schematic cross-sectional diagram of a manufacturing step following the step shown in FIG. 8.

FIG. 10 is a schematic cross-sectional diagram of a manufacturing step following the step shown in FIG. 9.

FIG. 11 is a schematic cross-sectional diagram of a manufacturing step following the step shown in FIG. 10.

FIG. 12 is a schematic cross-sectional diagram of a manufacturing step following the step shown in FIG. 11.

FIG. 13 is a schematic cross-sectional diagram of a manufacturing step following the step shown in FIG. 12.

FIG. 14 is a schematic cross-sectional diagram of a manufacturing step following the step shown in FIG. 13.

FIG. 15 is a schematic cross-sectional diagram of a manufacturing step following the step shown in FIG. 14.

FIG. 16 is an enlarged cross-sectional diagram of a structure around a gate layer of a variation example.

FIG. 17 is an enlarged cross-sectional diagram of a structure around a gate layer of a variation example.

FIG. 18 is an enlarged cross-sectional diagram of a structure around a gate layer of a variation example.

### DETAILED DESCRIPTION OF THE EMBODIMENTS

### Detailed Description

Details of several embodiments of a nitride semiconductor device of the present disclosure are described with reference to the accompanying drawings below.

To keep the description simple and clear, the constituting elements shown in the accompanying drawings are not necessarily drawn to certain scales. Moreover, for better understanding, sometimes shading lines may be omitted from the cross-sectional diagrams. The accompanying drawings are for illustrating the embodiments of the present disclosure, and are not to be construed as limitations to the present disclosure.

The detailed description below includes a device, a system and a method for implementing the exemplary embodiments of the present disclosure. The detailed description is intended for illustration purposes and is not to be construed as limitations to the embodiments of the present disclosure or application and use of these embodiments.

### [Brief Structure of Nitride Semiconductor Device]

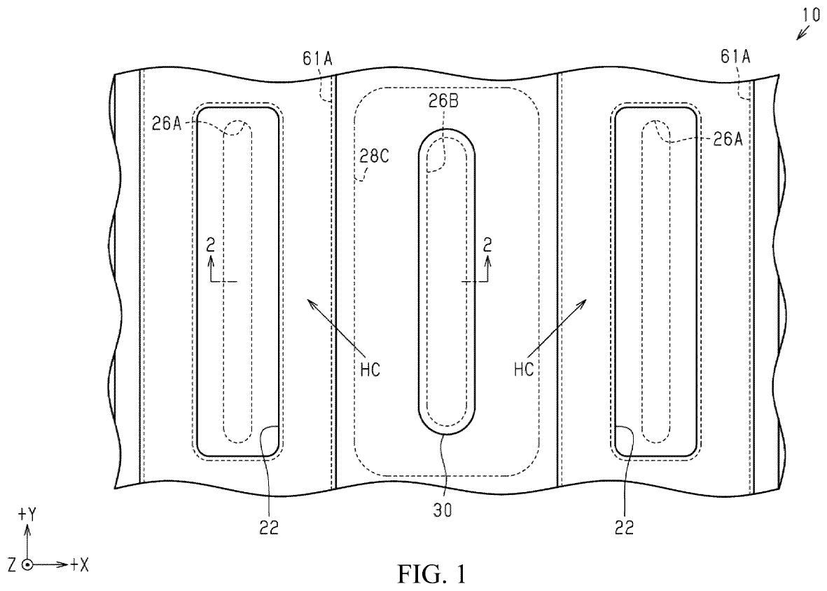

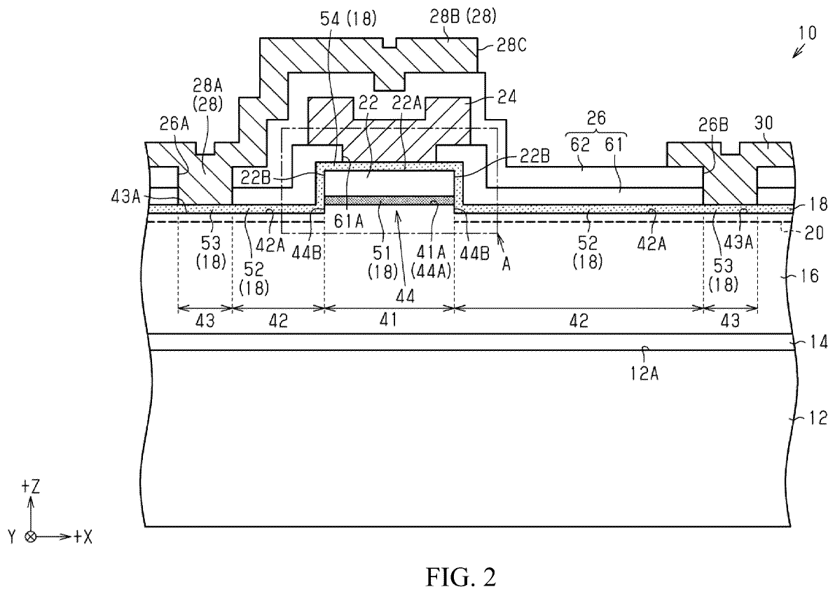

FIG. 1 shows a schematic plan view of an exemplary nitride semiconductor device 10 according to an embodiment. FIG. 2 shows a schematic cross-sectional diagram of the nitride semiconductor device 10, and is a cross-sectional diagram taken along the line 2-2 in FIG. 1. Moreover, in the nitride semiconductor device 10 shown in FIG. 1 and FIG. 2, for better description, the +Z direction is sometimes referred to as up/top, the −Z direction is sometimes referred to as down/bottom, the +X direction is sometimes referred to as right, and the −X direction is sometimes referred to as left. Unless otherwise specified, “a plan view” refers to observing the nitride semiconductor device 10 from the top along the Z axis. Moreover, unless otherwise specified, a thickness refers to a size measured along the Z direction.

In one example, the nitride semiconductor device 10 can be implemented by a high electron mobility transistor (HEMT) utilizing GaN. In the description below, a cross-section structure of the nitride semiconductor device 10 is described with reference to FIG. 2, and a planar structure of the nitride semiconductor device 10 is described with reference to FIG. 1.

As shown in FIG. 2, the nitride semiconductor device 10 can be configured as a HEMT utilizing a nitride semiconductor. The nitride semiconductor device 10 includes a substrate 12, a buffer layer 14 formed on the substrate 12, an electron travelling layer 16 formed on the buffer layer 14, and an electron supply layer 18 formed on the electron travelling layer 16. Further speaking, the nitride semiconductor device 10 includes a gate layer 22 formed on a portion of the electron supply layer 18 across from the electron supply layer 18, and a gate electrode 24 formed on the gate layer 22.

The substrate 12 can be formed of, for example, silicon (Si), silicon carbide (SiC), GaN, sapphire, or other substrate materials. The substrate 12 is, for example, a Si substrate. A thickness of the substrate 12 can be, for example, between about 200 μm and about 1500 μm. In FIG. 1 and FIG. 2, the Z direction in a situation where X, Y and Z axes are perpendicular to one another corresponds to a thickness direction of the substrate 12, and can also be referred to as a thickness direction of the electron supply layer 18.

The buffer layer 14 is formed on a substrate upper surface 12A of the substrate 12. The buffer layer 14 can be located between the substrate 12 and the electron travelling layer 16. In one example, the buffer layer 14 can be made of any material that allows easy epitaxial growth of the electron travelling layer 16. The buffer layer 14 can include one or more nitride semiconductor layers.

The buffer layer 14 can include at least one of an aluminum nitride (AlN) layer, an aluminum gallium nitride (AlGaN) layer, and a graded AlGaN layer with different aluminum (Al) compositions. For example, the buffer layer 14 can include one single AlN layer, one single AlGaN layer, a layer having an AlGaN/GaN superlattice structure, a layer having an AlN/AlGaN superlattice structure, or a layer having an AlN/GaN superlattice structure. Moreover, in order to suppress a leakage current in the buffer layer 14, impurities can be introduced to a portion of the buffer layer 14 such that the buffer layer 14 becomes semi-insulative. In this case, the impurities are, for example, carbon (C) or iron (Fe), and can have a concentration of, for example, 4×10¹⁶ cm⁻³ or more.

The electron travelling layer 16 is, for example, a GaN layer. A thickness of the electron travelling layer 16 is, for example, between about 0.5 μm and about 2 μm. Moreover, in order to suppress a leakage current in the electron travelling layer 16, impurities can also be introduced to a portion of the electron travelling layer 16 such that a semi-insulative region other than a surface-layer region of the electron travelling layer 16 is included. In this case, the impurities are, for example, C, and a peak concentration of the impurities in the electron travelling layer 16 is, for example, 1×10¹⁹ cm⁻³ or more.

In one example, the electron travelling layer 16 includes a first semiconductor layer formed on the buffer layer 14, a second semiconductor layer formed on the first semiconductor layer, and a third semiconductor layer formed on the second semiconductor layer. The first semiconductor layer can be said as being formed above the substrate 12, or can be said as being formed over the substrate 12. The third semiconductor layer is in contact with the electron supply layer 18. The first semiconductor layer, the second semiconductor layer and the third semiconductor layer are GaN layers having different impurity concentrations. The first semiconductor layer and the third semiconductor layer are non-doped GaN layers, and the second semiconductor layer is a C-doped GaN layer containing C as impurities.

The electron supply layer 18 is made of a nitride semiconductor having a band gap greater than that of the electron travelling layer 16. The electron supply layer 18 is, for example, an AlGaN layer. In this case, a band gap gets larger as the Al composition increases, and so the electron supply layer 18 implemented by an AlGaN layer has a band gap greater than the band gap of the electron travelling layer 16 implemented by a GaN layer. In one example, the electron supply layer 18 is made of AlxGa₁₋ₓN, where x is 0.1<x<0.4, and more preferably 0.2<x<0.3. A thickness of the electron supply layer 18 is, for example, between about 5 nm and about 20 nm.

The electron travelling layer 16 and the electron supply layer 18 are made of nitride semiconductors having different lattice constants from each other. Thus, the nitride semiconductor (for example, GaN) forming the electron travelling layer 16 and the nitride semiconductor (for example, AlGaN) forming the electron supply layer 18 form a heterojunction of a lattice mismatched system. Due to spontaneous polarization of the electron travelling layer 16 and the electron supply layer 18 as well as piezoelectric polarization caused by stress upon the electron supply layer 18 near a heterojunction interface, a conduction band energy level of the electron travelling layer 16 near the heterojunction interface is lower than a Fermi level. As such, at a position near the heterojunction interface between the electron travelling layer 16 and the electron supply layer 18 (for example, within a range distanced from the interface by several nm), a two-dimensional electron gas (2DEG) 20 is diffused within the electron travelling layer 16.

The electron supply layer 18 includes a first electron supply layer 51 and a second electron supply layer 52. Details related to the first electron supply layer 51 and the second electron supply layer 52 are described below.

The nitride semiconductor device 10 further includes a gate layer 22 formed on a portion (which sandwiches the first electron supply layer 51 described below on the electron supply layer 18) of the electron supply layer 18, a gate electrode 24 formed on the gate layer 22, and a passivation layer 26. The passivation layer 26 is formed on the electron supply layer 18, the gate layer 22 and the gate electrode 24, and includes a source opening 26A and a drain opening 26B. Moreover, the nitride semiconductor device 10 further includes a source electrode 28 in contact with the electron supply layer 18 through the source opening 26A, and a drain electrode 30 in contact with the electron supply layer 18 through the drain opening 26B.

The gate layer 22 is located between the source opening 26A and the drain opening 26B of the passivation layer 26, and is away from each of the source opening 26A and the drain opening 26B. Compared with the drain opening 26B, the gate layer 22 is located at a position closer to the drain opening 26A.

The gate layer 22 has a band gap less than that of the electron supply layer 18 and is made of a nitride semiconductor containing acceptor-type impurities. The gate layer 22 can be made of, for example, any material having a band gap less than that of the electron supply layer 18 which is an AlGaN layer. The gate layer 22 is, for example, a GaN layer (p-type GaN layer) doped with acceptor-type impurities. The acceptor-type impurities can include at least one of zinc (Zn), magnesium (Mg) and C. The maximum concentration of the acceptor-type impurities in the gate layer 22 is, for example, between about 1×10¹⁸ cm⁻³ and about 1×10²⁰ cm⁻³.

As described above, because the gate layer 22 includes the acceptor-type impurities, the energy levels of the electron travelling layer 16 and the electron supply layer 18 can be increased. Thus, in a region directly below the gate layer 22, the conduction band energy level of the electron travelling layer 16 near the heterojunction interface between the electron travelling layer 16 and the electron supply layer 18 is substantially same as or greater than the Fermi level. Hence, when a voltage of zero bias is not applied to the gate electrode 24, the 2DEG 20 is not formed in the electron travelling layer 16 in the region directly below the gate layer 22. On the other hand, the 2DEG 20 is formed in the electron travelling layer 16 in a region other than the region directly below the gate layer 22.

As such, due to the presence of the gate layer 22 doped with acceptor-type impurities, the 2DEG 20 is dissipated in the region directly below the gate layer 22. As a result, a normally off operation of a transistor is achieved. When an appropriate on voltage is applied to the gate electrode 24, a channel generated by the 2DEG 20 is formed in the electron travelling layer 16 in a region directly below the gate electrode 24, hence forming a source-drain conduction.

The gate electrode 24 is formed by one or more metal layers. The gate electrode 24 is, for example, a titanium nitride (TiN) layer. Alternatively, the gate electrode 24 can also be formed by layers including a first metal layer formed of a Ti-containing material, and a second metal layer laminated on the first metal layer and formed of a TiN-containing material. A thickness of the gate electrode 24 is, for example, between about 50 nm and about 200 nm.

The passivation layer 26 is formed on the electron supply layer 18. The passivation layer 26 can also be said as covering the electron supply layer 18. The passivation layer 26 can be made of a material containing any one of silicon nitride (SiN), silicon dioxide (SiO₂), silicon oxynitride (SiON), aluminum oxide (Al₂O₃), AlN, and aluminum oxynitride (AlON).

A thickness of the passivation layer 26 is greater than the thickness of the electron supply layer 18. The thickness of the passivation layer 26 is, for example, between about 300 nm and about 1000 nm. Moreover, the thickness of the passivation layer 26 can be changed as desired. The passivation layer 26 includes a first passivation layer 61 and a second passivation layer 62. Details related to structures of the first passivation layer 61 and the second passivation layer 62 are described below.

The source electrode 28 and the drain electrode 30 are disposed on an upper surface of the electron supply layer 18 across the gate layer 22 from each other. In the description below, sometimes a direction (the X direction) in which the source electrode 28 and the drain electrode 30 are arranged across the gate layer 22 from each other is referred to as a first direction in the plan view. Moreover, the first direction can also be said as a direction in which the source opening 26A and the drain opening 26B of the passivation layer 26 are arranged across the gate layer 22 from each other.

The source electrode 28 and the drain electrode 30 can be formed by one or more metal layers. For example, the source electrode 28 and the drain electrode 30 are formed by a combination of two or more types of metal layers, wherein the two or more types of metal layers are selected from a group consisting of a Ti layer, a TiN layer, an Al layer, an AlSiCu layer and an AlCu layer. At least a portion of the source electrode 28 fills the source opening 26A, and is in ohmic contact with the 2DEG 20 directly below the electron supply layer 18 through the source opening 26A. Similarly, at least a portion of the drain electrode 30 fills the drain opening 26B, and is in ohmic contact with the 2DEG 20 directly below the electron supply layer 18 through the drain opening 26B.

The source electrode 28, for example, includes a source contact 28A filling the source opening 26A, and a source field plate 28B formed on the passivation layer 26. The source field plate 28B is continuous with the source contact 28A, and is formed integrally with the source contact 28A. The source field plate 28B includes an end 28C located between the drain opening 26B and the gate layer 22 in the plan view. The source field plate 28B is away from the drain electrode 30. The source field plate 28B functions to alleviate an electric field concentration near an end of the gate electrode 24 and an end of the gate layer 22 when a gate voltage of zero bias is not applied to the gate electrode 24 and a drain voltage is applied to the drain electrode 30.

### [Detailed Structures of Electron Travelling Layer, Electron Supply Layer, Gate Layer and Passivation Layer]

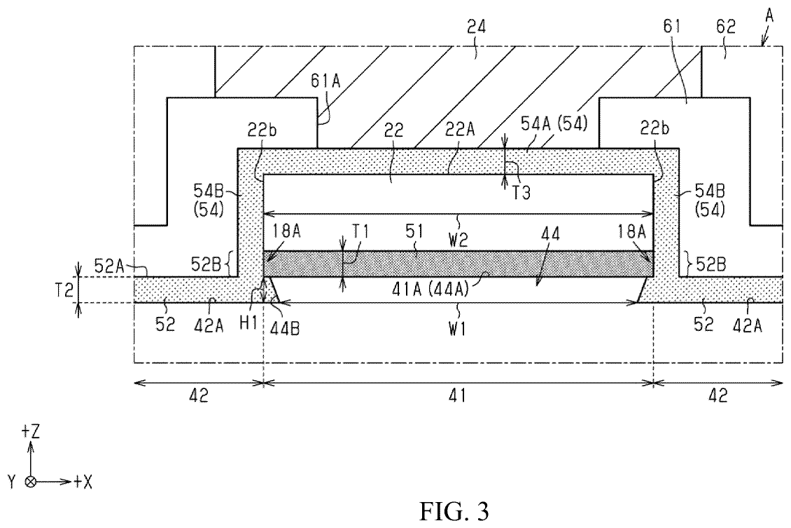

Referring to FIG. 2 and FIG. 3, detailed structures of the electron travelling layer, the electron supply layer, the gate layer and the passivation layer 26 are described below.

As shown in FIG. 2, the electron travelling layer 16 includes a first portion 41, a second portion 42 and a third portion 43. The first portion 41 is a portion in the electron travelling layer 16 located under the gate layer 22. The second portion 42 is a portion in the electron travelling layer 16 located between the gate layer 22 and the source opening 26A and between the gate layer 22 and the drain opening 26B in the plan view. The third portion 43 is a portion located under the source opening 26A and the drain opening 26B.

The first portion 41 has a protrusion 44 protruding over the second portion 42. The protrusion 44 includes an upper surface 44A, and a side surface 44B connected to the upper surface 44A. The upper surface 44A of the protrusion 44 is located higher than the upper surface 42A of the second portion 42, and is formed to have a planar shape parallel to the upper surface 42A. The protrusion 44 of this embodiment is formed on the entire first portion 41 in the plan view. Thus, the first portion 41 can also be said as protruding over the second portion 42. In this case, the upper surface 44A of the protrusion 44 and the upper surface 41A of the first portion 41 have the same significance.

FIG. 3 shows an enlarged diagram of a peripheral region (a range A) of the gate layer 22 in FIG. 2. Referring to FIG. 3, details of the protrusion 44 are described below.

A protruding height H1 of the protrusion 44 is, for example, 1 nm or more, and preferably 2 nm or more. Moreover, the protruding height H1 of the protrusion 44 is, for example, 10 nm or less, and preferably 5 nm or less. In addition, the protruding height H1 of the protrusion 44 is a difference between a position of the upper surface 44A of the protrusion 44 (the upper surface 41A of the first portion 41) and a position of the upper surface 42A of the second protrusion 42 in the thickness direction.

A width W1 of the protrusion 44 is, for example, between about 630 nm and about 750 nm. The width W1 of the protrusion 44 is a length of the protrusion 44 in the first direction. The protrusion 44 can have a cross section in a rectangular shape with a fixed width, or can have a cross section in a shape with a width varying partially or entirely. When the protrusion 44 has a cross section in a shape with a varying width, for example, an average value of the width of the protrusion 44 is taken as the width W1.

The width W1 of the protrusion 44 is, for example, shorter than a width W2 of the gate layer 22 formed on the protrusion 44. The with W2 of the gate layer 22 is, for example, between about 640 nm and about 760 nm. A difference between the width W2 of the gate layer 22 and the width W1 of the protrusion 44 (W2−W1) is, for example, between about 1 nm and about 10 nm. Moreover, the width W1 of the protrusion 44 can also be same as the width W2 of the gate layer 22.

In an example in FIG. 3, the protrusion 44 has a shape with a gradually increasing width in the first direction or a gradually decreasing width in the first direction as getting close to the top. The side surface 44B of the protrusion 44 is a sloped plane shape or a curved plane shape crossing the thickness direction. A width of the protrusion 44 is shorter than the width W2 of the gate layer 22 throughout the thickness direction. In an example shown in FIG. 3, the side surface 44B is a sloped plane such that the width of the protrusion 44 gradually increases in the first direction as getting close to the top. The side surface 44B can also be a sloped plane such that the width of the protrusion 44 gradually decreases in the first direction as getting close to the top. Moreover, the side surface 44B can be a curved plane as an inverted cone shape such that the width of the protrusion 44 gradually increases in the first direction as getting close to the top, or can be a curved plane as an upright cone shape such that the width of the protrusion 44 gradually decreases in the first direction as getting close to the top. Moreover, in FIG. 3, to better understand the shape of the side surface 44B of the protrusion 44, the side surface 44B is exaggeratedly shown in a manner that is more recessed in the first direction in the drawing.

As shown in FIG. 2, the electron supply layer 18 includes a first electron supply layer 51, the second electron supply layer 52 and a third electron supply layer 53. The first electron supply layer 51 is formed on the upper surface 41A of the first portion 41 of the electron travelling layer 16 (the upper surface 44A of the protrusion 44), and is located under the gate layer 22. The second electron supply layer 52 is formed on the second portion 42 of the electron travelling layer 16, and is connected to the first electron supply layer 51. The third electron supply layer 53 is formed on the third portion 43 of the electron travelling layer 16, and is located under the source opening 26A and under the drain opening 26B and connected to the second electron supply layer 52.

As shown in FIG. 3, a thickness T1 of the first electron supply layer 51 is, for example, between about 5 nm and about 20 nm. A thickness T2 of the second electron supply layer 52 is, for example, between about 5 nm and about 20 nm.

A material forming the second electron supply layer 52 is, for example, same as a material forming the first electron supply layer 51. Moreover, the material forming the second electron supply layer 52 can also be different from the material forming the first electron supply layer 51. In one example, the first electron supply layer 51 is an AlGaN layer, and the second electron supply layer 52 is an AlGaN layer having an Al composition less than that of the first electron supply layer 51. In this case, a gate threshold voltage can be increased. Thus, a gate leakage current can be suppressed since the gate threshold voltage is increased. Moreover, in another example, the first electron supply layer 51 is an AlGaN layer, and the second electron supply layer 52 is an AlGaN layer having an Al composition greater than that of the first electron supply layer 51. In this case, an amount of the 2DEG 20 formed between a gate and a source and between a gate and a drain is increased, so that a reduced on resistance can be achieved.

The thickness T2 of the second electron supply layer 52 is, for example, same as the thickness T1 of the first electron supply layer 51. Moreover, the thickness T2 of the second electron supply layer 52 can also be greater than the thickness T1. In this case, an amount of the 2DEG 20 formed between a gate and a source and between a gate and a drain is increased, so that a reduced on resistance can be achieved. Moreover, the thickness T2 of the second electron supply layer 52 can also be less than the thickness T1.

The thickness T2 of the second electron supply layer 52 in FIG. 3 is, for example, same as the protruding height H1 of the protrusion 44 of the electron travelling layer 16 or less than the protruding height H1. In other words, in the thickness direction, an upper surface 52A of the second electron supply layer 52 is located at a position same as the upper surface 44A of the protrusion 44, or is located at a position lower than the upper surface 44A of the protrusion 44. In this case, the second electron supply layer 52 includes a connecting portion 52B formed to be partially thicker along the side surface 44B of the protrusion 44, wherein the connecting portion 52B is connected to the first electron supply layer 51.

Moreover, the thickness T2 of the second electron supply layer 52 can be greater than the protruding height H1 of the protrusion 44 of the electron travelling layer 16. In other words, in the thickness direction, the upper surface 52A of the second electron supply layer 52 can also be located at a position higher than the upper surface 44A of the protrusion 44. In this case, ease of manufacturing is provided since the second electron supply layer 52 does not need the connecting portion 52B.

A material forming the third electron supply layer 53 is, for example, same as the material forming the second electron supply layer 52. A thickness (not shown) of the third electron supply layer 53 is, for example, between about 5 nm and about 20 nm. The thickness of the third electron supply layer 53 is, for example, same as the thickness T2 of the second electron supply layer 52.

As shown in FIG. 2, the electron supply layer 18 further includes a covering portion 54 covering the upper surface 22A and the side surface 22B of the gate layer 22 and connected to the second electron supply layer 52. As shown in FIG. 3, the covering portion 54 includes an upper part 54A covering the upper surface 22A of the gate layer 22, and a side part 54B covering the side surface 22B of the gate layer 22. The upper part 54A of the covering portion 54 is sandwiched between the gate layer 22 and the gate electrode 24. The gate electrode 24 is in contact with the gate layer 22 through the upper part 54A of the covering portion 54. A lower end of the covering portion 54 at the side part 54B is connected to the second electron supply layer 52. The upper part 54A of the covering portion 54 between the gate layer 22 and the gate electrode 24 provides a function of increasing the Schottky barrier between the gate layer 22 and the gate electrode 24.

A material forming the covering portion 54 is, for example, same as the material forming the second electron supply layer 52. A thickness T3 of the covering portion 54 is, for example, between about 5 nm and about 20 nm. The thickness T3 of the covering portion 54 is, for example, same as the thickness T2 of the second electron supply layer 52. In one example, the thickness T3 of the covering portion 54 is greater than the thickness T1 of the first electron supply layer 51. In this case, the Schottky barrier between the gate layer 22 and the gate electrode 24 can be increased. Moreover, the thickness T3 of the covering portion 54 can be same as the thickness T1 or be less than the thickness T1.

Herein, in the electron supply layer 18, the first electron supply layer 51 and the second electron supply layer 52 are layers formed at timings different from each other. More specifically, the first electron supply layer 51 (to be described as an initially formed electron supply layer below) is a layer formed earlier than the gate layer 22, and the second electron supply layer 52 (to be described as a re-formed electron supply layer below) is a layer formed later than the gate layer 22. In this drawing, a part formed by the initially formed electron supply layer is represented by shading in darker dots, and a part formed by the re-formed electron supply layer is represented by shading in lighter dots.

As shown in FIG. 3, in an example of the electron supply layer 18, an interface 18A is present between the first electron supply layer 51 as the initially formed electron supply layer and the second electron supply layer 52 as the re-formed electron supply layer. The interface 18A is formed on an end face of the first electron supply layer 51 in the first direction. Moreover, in addition to being formed on the end face, the interface 18A can also be formed on a lower surface of an end of the first electron supply layer 51 in the first direction. In addition, the electron supply layer 18 can also be configured to exclude the interface 18A. For example, when the materials forming the first electron supply layer 51 and the second electron supply layer 52 are the same, the interface 18A is not formed.

The third electron supply layer 53 and the covering portion 54 are formed by the re-formed electron supply layer. That is to say, the second electron supply layer 52, the third electron supply layer 53 and the covering portion 54 are a continuous re-formed electron supply layer formed at a same timing.

As shown in FIG. 2, the passivation layer 26 includes a first passivation layer 61 and a second passivation layer 62. The first passivation layer 61 is formed on the second electron supply layer 52 and on the gate layer 22. The first passivation layer 61 can also be said as covering the second electron supply layer 52 and the gate layer 22.

The first passivation layer 61 includes a gate opening 61A formed on a portion of the gate layer 22. At least a portion of the gate electrode 24 fills the gate opening 61A, and is in contact with the electron supply layer 18 (the upper part 54A of the covering portion 54) through the gate opening 61A. The first passivation layer 61 is a layer for protecting the second electron supply layer 52 from etching damage during etching while the gate electrode 24 is formed.

The second passivation layer 62 is formed on the first passivation layer 61 and the gate electrode 24. The second passivation layer 62 can also be said as covering the first passivation layer 61 and the gate electrode 24. The source field plate 28B of the source electrode 28 is formed on the second passivation layer 62.

A material forming the first passivation layer 61 is same as or different from a material forming the second passivation layer 62. In one example, the first passivation layer 61 is a layer structured to have a greater density, and the second passivation layer 62 is a layer structured to have a lower density. With the presence of the first passivation layer 61 and the second passivation layer 62 as the passivation layer 26, the second passivation layer 62 that is not in contact with the electron supply layer 18 is implemented by a layer structured to have a lower density, and so manufacturing processes can be simplified.

A thickness of the first passivation layer 61 is, for example, between about 95 nm and about 105 nm. A thickness of the second passivation layer 62 is, for example, between about 95 nm and about 105 nm. The thickness of the second passivation layer 62 is, for example, greater than the thickness of the first passivation layer 61. Moreover, the thickness of the second passivation layer 62 can also be same as the thickness of the first passivation layer 61, or be less than the thickness of the first passivation layer 61. Moreover, in the passivation layer 26, an interface (not shown) can be present between the first passivation layer 61 and the second passivation layer 62.

### [Planar Structure of Nitride Semiconductor Device]

Next, the planar structure of the nitride semiconductor device 10 is described with reference to FIG. 1 below. In FIG. 1, the drawings of the passivation layer 26 and the source electrode 28 are omitted, and the source opening 26A, the drain opening 26B and the gate opening 61A of the passivation layer 26, and the end 28C of the source electrode 28 are depicted in dotted lines.

The nitride semiconductor device 10 includes, for example, an active region conducive to operations of transistors, and a non-active region (not shown) not conducive to operations of transistors. In one example, the active region and the non-active region are alternately arranged in the Y direction.

Within the active region of the nitride semiconductor device 10, the source electrode 28 (referring to FIG. 2), the gate electrode 24 and the drain electrode 30 are disposed to be adjacent in the first direction (the X direction) on the electron supply layer 18 (referring to FIG. 2). A combination of the source electrode 28, the gate electrode 24 and the drain electrode 30 adjacent to one another in the first direction forms one HEMT unit HC. In the example in FIG. 1, within the active region, two HEMT units HC are disposed in the X direction. Moreover, more HEMT units HC can in fact be disposed in each active region.

### [Manufacturing Method of Nitride Semiconductor Device]

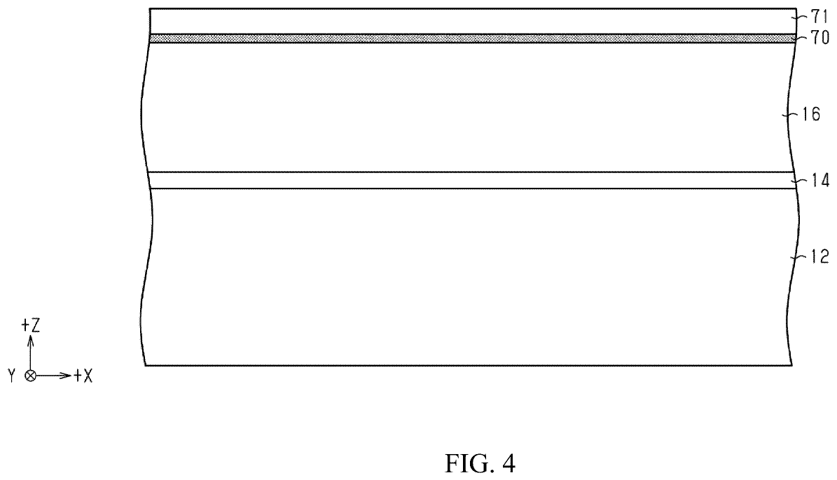

Referring to FIG. 4 to FIG. 15, an exemplary manufacturing method of the nitride semiconductor device 10 is described below. Moreover, in FIG. 4 to FIG. 15, the constituting elements same as the constituting elements in FIG. 2 are denoted with the same numerals or symbols.

As shown in FIG. 4, the manufacturing method of the nitride semiconductor device 10 includes a step of sequentially forming the buffer layer 14 and the electron travelling layer 16 on the substrate 12. The substrate 12 is, for example, a Si substrate. The buffer layer 14 and the electron travelling layer 16 can be epitaxially grown by means of, for example, metal organic chemical vapor deposition (MOCVD).

Although details are omitted from the drawing, in one example, the buffer layer 14 is a multi-layer buffer layer, and after an AlN layer (a first buffer layer) is formed on the substrate 12, a graded AlGaN layer (a second buffer layer) is formed on the AlN layer. The graded AlGaN layer is formed by, for example, sequentially laminating three AlGaN layers respectively having Al compositions of 75%, 50% and 25%, starting from one side close to the AlN layer.

Next, the electron travelling layer 16 is formed on the buffer layer 14. The electron travelling layer 16 is formed on the substrate 12 across from the buffer layer 14. The electron travelling layer 16 is, for example, a GaN layer. Although details are omitted from the drawing, in one example, after a non-doped GaN layer (a first semiconductor layer) is formed on the buffer layer 14, a C-doped GaN layer (a second semiconductor layer) is formed on the non-doped GaN layer. Further, a non-doped GaN layer (a third semiconductor layer) is formed on the C-doped GaN layer.

The manufacturing method of the nitride semiconductor device 10 includes a step of forming an initially formed electron supply layer 70 on the electron travelling layer 16 made of a nitride semiconductor. Moreover, the manufacturing method of the nitride semiconductor device 10 includes: a step of forming the gate layer 22 made of a nitride semiconductor containing acceptor-type impurities on the initially formed electron supply layer 70, and a step of forming the first electron supply layer 51 by removing a portion of the initially formed electron supply layer 70 by etching to preserve a portion located under the gate layer 22 and expose the electron travelling layer 16.

As shown in FIG. 4, the initially formed electron supply layer 70 is formed on the electron travelling layer 16. The initially formed electron supply layer 70 is a layer for forming the first electron supply layer 51, and is, for example, an AlGaN layer. The initially formed electron supply layer 70 is made of a nitride semiconductor having a band gap greater than that of the electron travelling layer 16. The initially formed electron supply layer 70 can be epitaxially grown by means of, for example, MOCVD.

Next, a first nitride semiconductor layer 71 is formed on the initially formed electron supply layer 70. The first nitride semiconductor layer 71 is a layer for forming the gate layer 22, and is, for example, a GaN layer containing Mg as acceptor-type impurities. The first nitride semiconductor layer 71 can be epitaxially grown by means of MOCVD. As an example, the first nitride semiconductor layer 71 is formed on the initially formed electron supply layer 70 by doping GaN with Mg during the GaN growth.

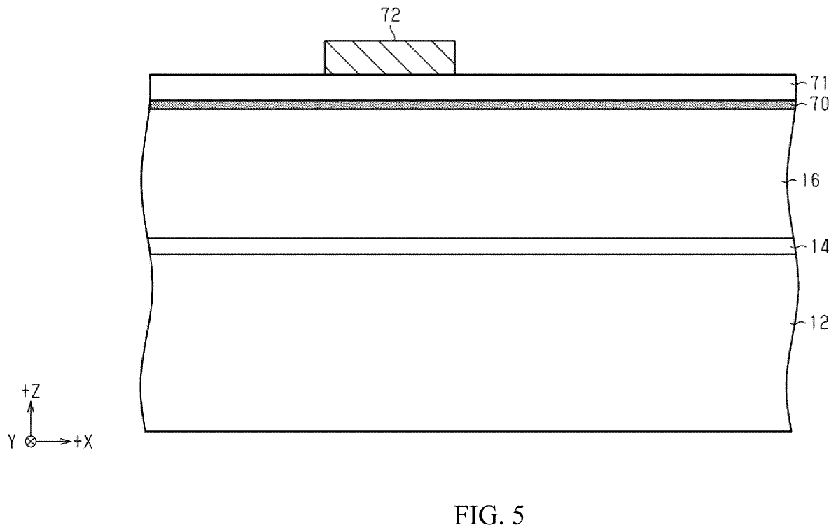

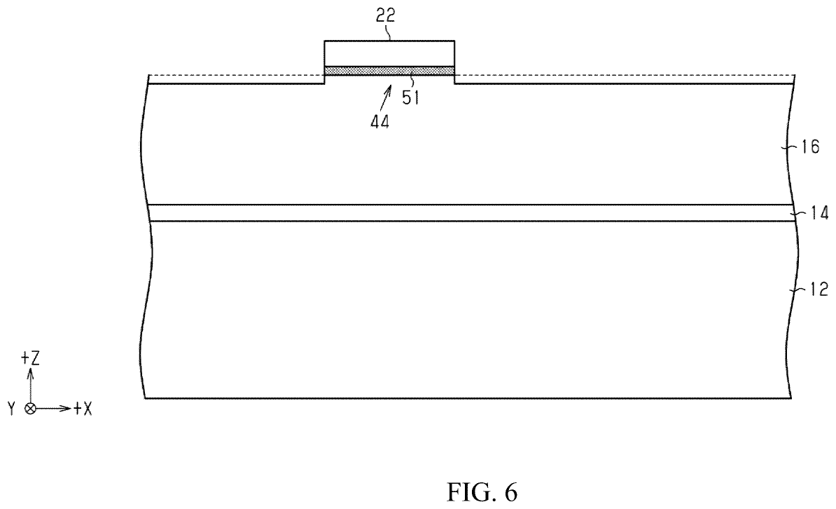

Next, as shown in FIG. 5, a mask 72 is formed on a portion of the first nitride semiconductor layer 71. Then, as shown in FIG. 6, the first nitride semiconductor layer 71 and the initially formed electron supply layer 70 are selectively removed by etching to expose a portion of the upper surface of the electron travelling layer 16 in the portion where the mask 72 is not formed in the plan view. The mask 72 is then removed. As such, the gate layer 22 which is a remaining portion of the first nitride semiconductor layer 71 is formed, and the first electron supply layer 51 which is a remaining portion of the initially formed electron supply layer 70 is formed.

Herein, when a portion of the initially formed electron supply layer 70 is removed by etching, a portion on the side of the upper surface of the electron travelling layer 16 in the portion where the mask 72 is not formed is also removed. As such, the protrusion 44 is formed in a region (the first portion 41) of the electron travelling layer 16 located under the gate layer 22. The protruding height H1 of the protrusion 44 can be adjusted by means of changing the amount of etching of the electron travelling layer 16.

It is possible that an etching rate of a material (for example, AlGaN) forming the initially formed electron supply layer 70 is faster than an etching rate of a material (for example, GaN) forming the electron travelling layer 16. In this case, when a portion on the side of the upper surface of the electron travelling layer 16 is etched, it recesses into the portion located under the gate layer 22, and the electron travelling layer 16 is removed. As a result, as shown in FIG. 3, the width W1 of the protrusion 44 is less than the width W2 of the gate layer 22.

The manufacturing method of the nitride semiconductor device 10 includes: a step of forming a re-formed electron supply layer 73 connected to the first electron supply layer 51 on the electron travelling layer 16 exposed by etching, a step of forming the passivation layer 26 on the re-formed electron supply layer 73, and a step of forming the gate electrode 24 on the gate layer 22.

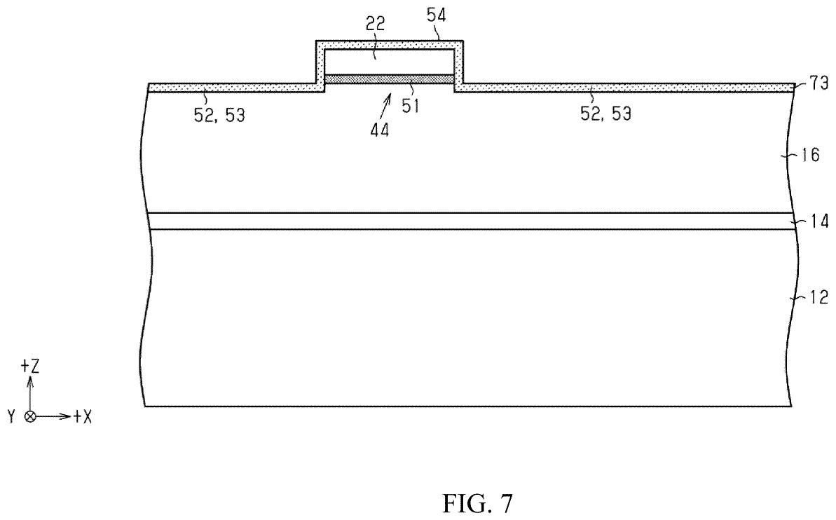

As shown in FIG. 7, the re-formed electron supply layer 73 is formed on the electron travelling layer 16 and the gate layer 22. The re-formed electron supply layer 73 is a layer covering a portion on the electron travelling layer 16 and the gate layer 22, and is, for example, an AlGaN layer. The re-formed electron supply layer 73 is a continuous layer formed integrally by the second electron supply layer 52, the third electron supply layer 53 and the covering portion 54. The re-formed electron supply layer 73 is made of a nitride semiconductor having a band gap greater than that of the electron travelling layer 16. The re-formed electron supply layer 73 can be epitaxially grown by means of, for example, MOCVD.

In one example, the initially formed electron supply layer 70 is an AlGaN layer, and the re-formed electron supply layer 73 is an AlGaN layer having an Al composition less than that of the initially formed electron supply layer 70. In another example, the initially formed electron supply layer 70 is an AlGaN layer, and the re-formed electron supply layer 73 is an AlGaN layer having an Al composition greater than that of the initially formed electron supply layer 70.

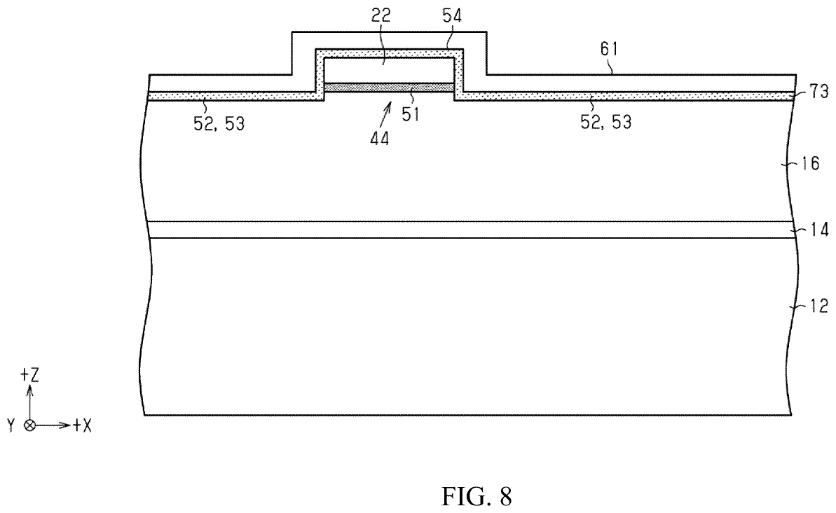

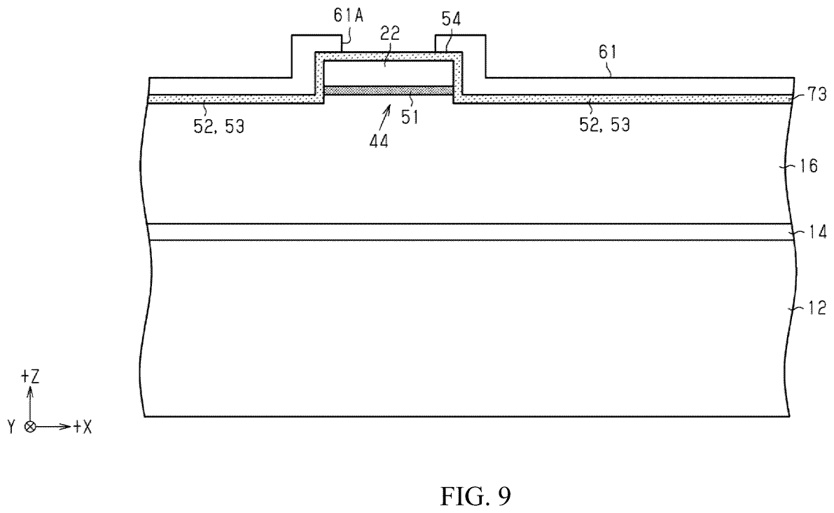

Next, as shown in FIG. 8, the first passivation layer 61 is formed on the re-formed electron supply layer 73. Then, as shown in FIG. 9, the gate opening 61A that exposes the re-formed electron supply layer 73 located on the gate layer 22 is formed in the first passivation layer 61. The first passivation layer 61 is, for example, a SiN layer. The first passivation layer 61 is formed by means of, for example, low-pressure chemical vapor deposition (LPCVD). The gate opening 61A is formed by selectively removing a portion of the portion of the first passivation layer 61 located on the gate layer 22 by means of photolithography and etching by using a mask.

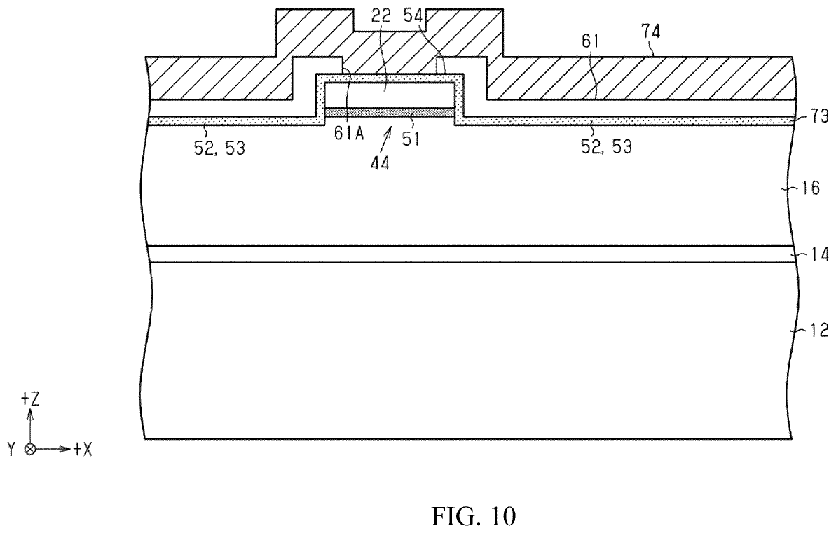

Next, as shown in FIG. 10, a first metal layer 74 is formed on the first passivation layer 61 and in the gate opening 61A. The first metal layer 74 is a layer for forming the gate electrode 24, and is, for example, a TiN layer. The first metal layer 74 can be formed by means of, for example, sputtering.

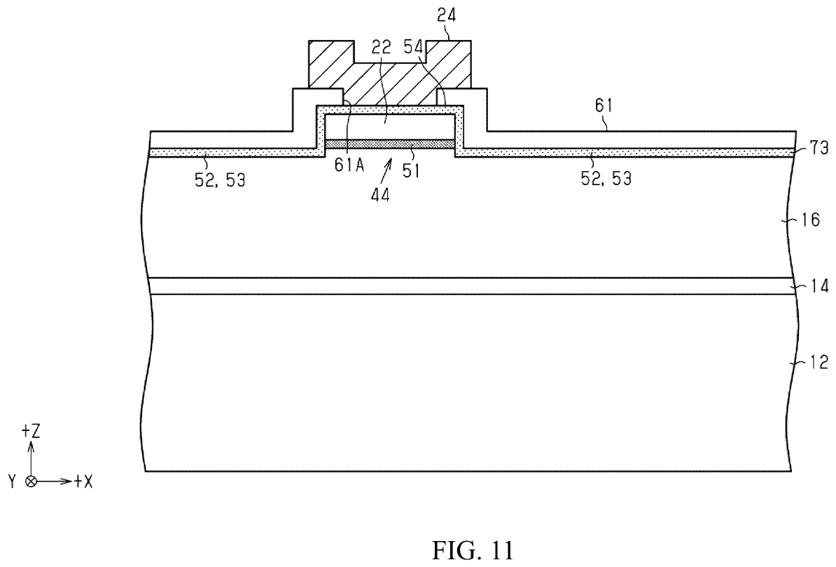

Next, as shown in FIG. 11, a portion of the first metal layer 74 is selectively removed. As such, the gate electrode 24 which is a remaining portion of the first metal layer 74 is formed. The gate electrode 24 is formed to be connected to the re-formed electron supply layer 73 (the covering portion 54) exposed from the gate opening 61A of the first passivation layer 61. The gate electrode 24 is formed by selectively removing a portion of the first metal layer 74 by means of photolithography and etching by using a mask.

Herein, etching for selectively removing a portion of the first metal layer 74 is performed in a state in which the first passivation layer 61 is formed on the re-formed electron supply layer 73. Thus, the first passivation layer 61 protects the re-formed electron supply layer 73 to prevent it from being etched. As such, etching damage is prevented from occurring in the re-formed electron supply layer 73 (more particularly, the second electron supply layer 52).

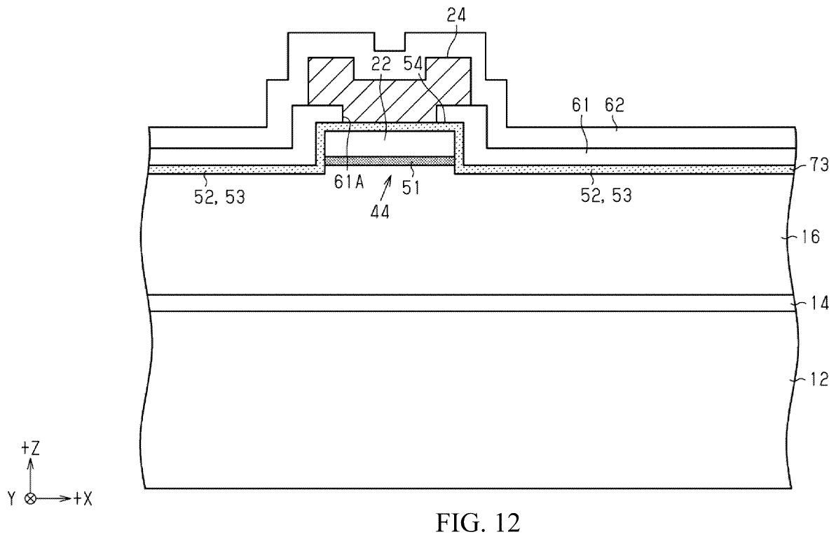

Next, as shown in FIG. 12, a second passivation layer 62 is formed on the first passivation layer 61 and the gate electrode 24. The second passivation layer 62 is formed to cover a portion on the first passivation layer 61 and the gate electrode 24. The second passivation layer 62 is, for example, a SiN layer. The second passivation layer 62 can be formed by means of, for example, LPCVD. Moreover, the step of forming the passivation layer 26 on the re-formed electron supply layer 73 described above includes: a step of forming the first passivation layer 61, and a step of forming the second passivation layer 62.

The manufacturing method of the nitride semiconductor device 10 includes a step of forming the source electrode 28 and the drain electrode 30 on the re-formed electron supply layer 73.

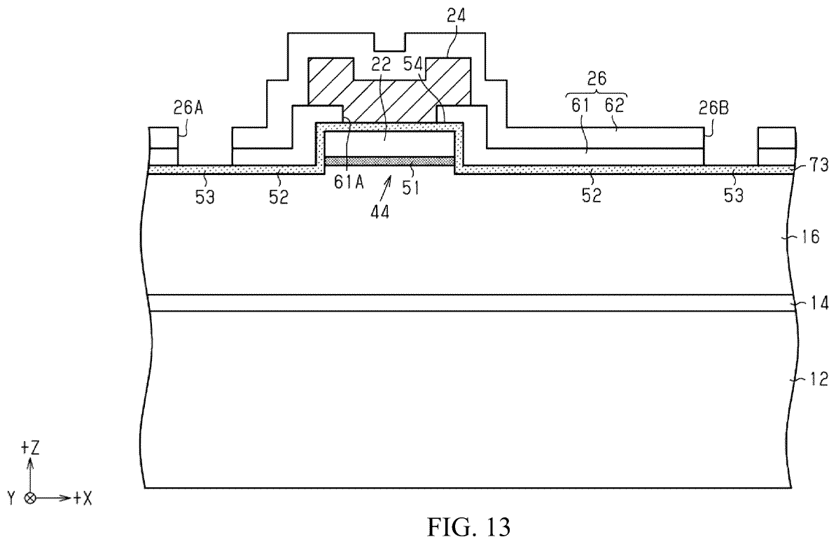

As shown in FIG. 13, in the first passivation layer 61 and the second passivation layer 62, the source opening 26A and the drain opening 26B exposing the re-formed electron supply layer 73 are formed. The source opening 26A and the drain opening 26B are formed by selectively removing a portion of the first passivation layer 61 and the second passivation layer 62 by means of photolithography and etching by using a mask.

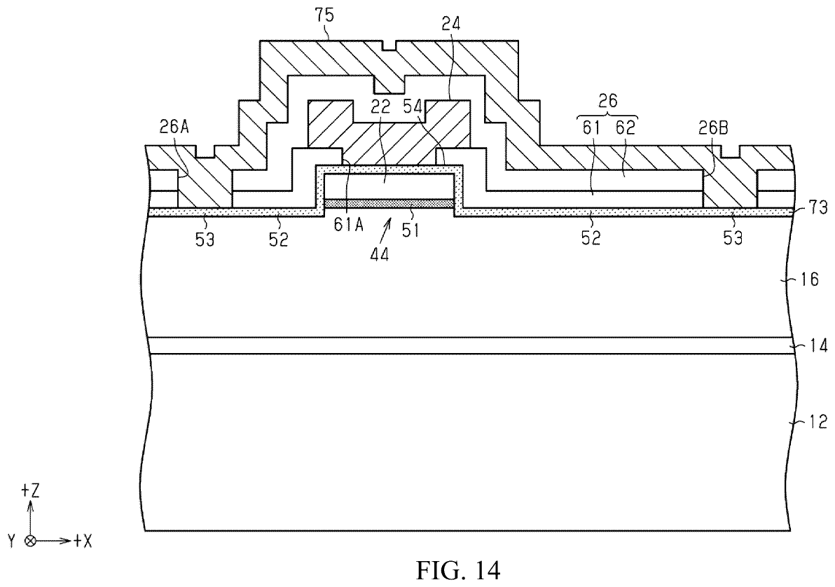

Next, as shown in FIG. 14, a second metal layer 75 is formed on the second passivation layer 62 and in the source opening 26A and the drain opening 26B. The second metal layer 75 is a layer for forming the source electrode 28 and the drain electrode 30, and is, for example, a Ti layer. The second metal layer 75 can be formed by means of, for example, sputtering.

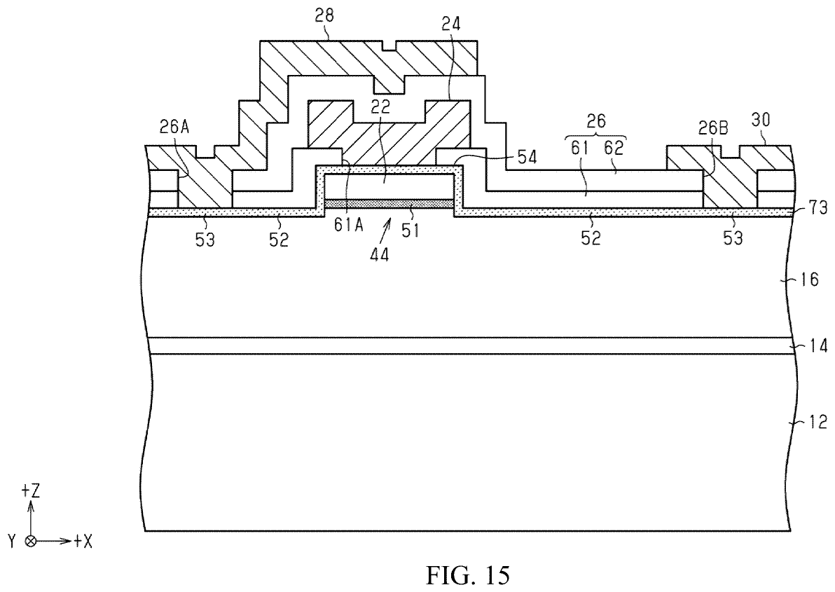

Next, as shown in FIG. 15, a portion of the second metal layer 75 is selectively removed. As such, the source electrode 28 and the drain electrode 30 which are a remaining portion of the second metal layer 75 are formed. The source electrode 28 is formed to be in contact with the re-formed electron supply layer 73 exposed from the source opening 26A of the first passivation layer 61 and the second passivation layer 62. The drain electrode 30 is formed to be in contact with the re-formed electron supply layer 73 exposed from the drain opening 26B of the first passivation layer 61 and the second passivation layer 62. The source electrode 28 and the drain electrode 30 are formed by selectively removing a portion of the second metal layer 75 by means of photolithography and etching by using a mask. With the steps above, the nitride semiconductor device 10 can be obtained.

### [Functions]

Next, the functions of the nitride semiconductor device 10 are described below.

In a conventional nitride semiconductor device having a gate layer formed on an electron supply layer, etching performed while the gate layer is formed causes etching damage in an electron supply layer located between the gate layer and a source electrode and between the gate layer and a drain electrode. The etching damage caused in the electron supply layer accounts for the main reason for a change in electrical characteristics of a 2DEG in an electron travelling layer. The electron supply layer with the etching damage becomes being in a state in which it can easily capture surrounding electrons. It is considered that the reason of the above is due to that the crystal structure of the electron supply layer has become unstable. In the event of etching damage caused in the electron supply layer, when a current flows by using the 2DEG as a conduction path, a portion of electrons moving in the 2DEG are captured by the electron supply layer, thereby incurring a change in electrical characteristics of the 2DEG.

In the nitride semiconductor device 10 of the embodiment, the electron supply layer 18 includes the first electron supply layer 51 located under the gate layer 22, and a second electron supply layer 52 located between the gate layer 22 and the source opening 26A and between the gate layer 22 and the drain opening 26B and connected to the first electron supply layer 51. In this case, by configuring the first electron supply layer 51 and the second electron supply layer 52 to be made by different layers formed at different timings, the second electron supply layer 52 can become an intact layer without any etching damage.

More specifically, after the initially formed electron supply layer 70 is formed on the electron travelling layer 16, the gate layer 22 is formed on the initially formed electron supply layer 70. During etching performed while the gate layer 22 is formed, a portion of the initially formed electron supply layer 70 other than the portion located under the gate layer 22 is completely removed. Then, on the electron travelling layer 16 exposed by removing the initially formed electron supply layer 70, the re-formed electron supply layer 73 is formed, and the re-formed electron supply layer 73 is used as the second electron supply layer 52. In this case, after the initially formed electron supply layer 70 containing etching damage caused while the gate layer 22 is formed is removed, the second electron supply layer 52 which is the newly formed electron supply layer 73 is formed. Thus, the second electron supply layer 52 becomes an intact layer without any etching damage caused while the gate layer 22 is formed.

Since the second electron supply layer 52 is an intact layer, when a current flows in the 2DEG 20 as a conduction path, electrons moving in the 2DEG 20 are suppressed from being captured by the second electron supply layer 52. As a result, electrical characteristics of the 2DEG 20 in the nitride semiconductor device 10 are stable. Moreover, in designs for the nitride semiconductor device 10 having desired electrical characteristics of the 2DEG 20, it is not necessary to consider control parameters related to an amount of etching. This is further conducive to stabilizing electrical characteristics of the 2DEG 20 in the nitride semiconductor device 10.

### Effects

The following effects can be achieved by the nitride semiconductor device 10.

(1) A nitride semiconductor device 10 includes: an electron travelling layer 16; an electron supply layer 18 formed on the electron travelling layer 16; a gate layer 22 formed on a portion of the electron supply layer 18; a gate electrode 24 formed on the gate layer 22; a passivation layer 26 covering the electron supply layer 18, the gate layer 22 and the gate electrode 24, and having a source opening 26A and a drain opening 26B; a source electrode 28 in contact with the electron supply layer 18 through the source opening 26A; and a drain electrode 30 in contact with the electron supply layer 18 through the drain opening 26B. The electron travelling layer 16 includes: a first portion 41 located under the gate layer 22; and a second portion 42 located between the gate layer 22 and the source opening 26A, and between the gate layer 22 and the drain opening 26B. The electron supply layer 18 includes: a first electron supply layer 51 formed on the first portion 41 and located under the gate layer 22; and a second electron supply layer 52 formed on the second portion 42 and connected to the first electron supply layer 51.

According to the configuration above, the electron supply layer 18 (the second electron supply layer 52) that is intact without any etching damage can be present between the gate electrode 24 and the source electrode 28 and between the gate electrode 24 and the drain electrode 30 in a plan view. As such, electrical characteristics of a two-dimensional electron gas (2DEG) 20 in the nitride semiconductor device 10 can become stable.

(2) A thickness T2 of the second electron supply layer 52 is same as a thickness T1 of the first electron supply layer 51. In this case, a difference between an amount of the 2DEG 20 formed between a gate and a source and between a gate and a drain and an amount of the 2DEG 20 formed directly below the gate electrode 24 when the gate electrode 24 is applied with an on voltage can be reduced.

(3) A thickness T2 of the second electron supply layer 52 is greater than a thickness T1 of the first electron supply layer 51. In this case, an amount of the 2DEG 20 formed between a gate and a source and between a gate and a drain is increased, so that reduced on resistance can be achieved.

(4) The electron supply layer 18 includes a covering portion 54 covering an upper surface 22A of the gate layer 22. An upper part 54A of the covering portion 54 covering the upper surface 22A of the gate layer 22 is sandwiched between the gate layer 22 and the gate electrode 24. In this case, since the electron supply layer 18 (the upper part 54A of the covering portion 54) is interposed between the gate layer 22 and the gate electrode 24, a Schottky barrier between the gate layer 22 and the gate electrode 24 can be increased. Thus, a gate leakage current passing through the gate layer 22 can be reduced.

(5) The covering portion 54 includes a side part 54B covering a side surface 22B of the gate layer 22 and connected to the second electron supply layer 52. In this case, the second electron supply layer 52 which is an intact layer can be formed as a single layer and the upper part 54A of the covering portion 54 in charge of a function of increasing the Schottky barrier can be formed by one single formation process.

(6) A thickness T3 of the covering portion 54 is same as a thickness T1 of the first electron supply layer 51 or less than the thickness T1. In this case, a situation where the Schottky barrier becomes overly high and the on resistance becomes overly large due to the increased Schottky barrier can be suppressed.

(7) A thickness T3 of the covering portion 54 is greater than a thickness T1 of the first electron supply layer 51. In this case, the Schottky barrier can be increased. Thus, a gate leakage current passing through the gate layer 22 can be further reduced.

(8) The first portion 41 of the electron travelling layer 16 has a protrusion 44 protruding over the second portion 42. The first electron supply layer 51 of the electron supply layer 18 is formed on the protrusion 44. In this case, the initially formed electron supply layer 70 with etching damage can be more completely removed. Accordingly, the effect described in (1) can be more significantly achieved.

### Variation Example

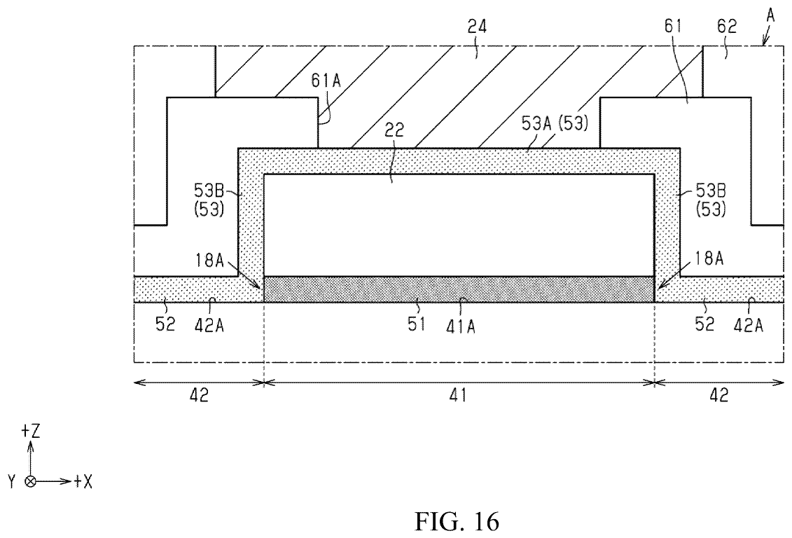

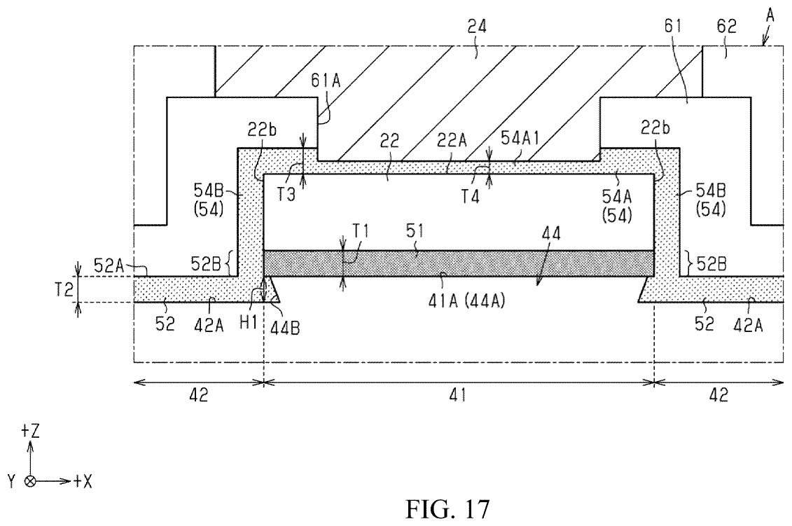

The embodiment described above can be implemented as the variations below. Given that there are no technical contradictions, the embodiment described above can be used in combination with the variation examples below. Moreover, in the variation examples below, parts that are in common with the embodiment describe above are denoted with the same numerals and symbols, and the related description is omitted.
As shown in FIG. 16, the first portion 41 of the electron travelling layer 16 can also be configured to exclude the protrusion 44. In this case, the upper surface 41A of the first portion 41 and the upper surface 42A of the second portion 42 are located at a same position in the thickness direction; that is to say, the upper surface 41A and the upper surface 42A are coplanar. Moreover, the electron travelling layer 16 of the configuration above can be formed in a manner below. In the step of removing a portion of the initially formed electron supply layer 70 by etching (referring to FIG. 6) in the manufacturing method of the nitride semiconductor device 10, etching is performed on the initially formed electron supply layer 70 without removing a portion on the side of the upper surface of the electron travelling layer 16. As such, the electron travelling layer 16 without the shape of the protrusion 44 can be formed.
As shown in FIG. 17, a thickness T4 of a part 54A1 of the upper part 54A of the covering portion 54 located under the gate electrode 24 can also be partially decreased. The thickness T4 of the part 54A1 is, for example, between about 1 nm and about 10 nm. A ratio of the thickness T4 of the part 54A1 to the thickness T3 of the covering portion 54 other than the part 54A1 (T4/T3) is, for example, between about 1 and about 10. Moreover, a ratio of the thickness T4 of the part 54A1 to the thickness T2 of the second electron supply layer 52 (T4/T2) is, for example, between about 1 and about 10. By adjusting the thickness T4 of the part 54A1, a height of the Schottky barrier between the gate layer 22 and the gate electrode 24 can be controlled. For example, by configuring the thickness T2 of the second electron supply layer 52 to be greater than the thickness T1 of the first electron supply layer 51, an amount of the 2DEG 20 produced can be increased. In this case, by configuring the thickness T4 of the part 54A1 to be less than the thickness T2 of the second electron supply layer 52, the Schottky barrier between the gate layer 22 and the gate electrode 24 can be prevented from getting overly large.

Moreover, the covering portion 54 of the configuration above can be formed in a manner below. In the step of forming the gate opening 61A in the manufacturing method of the nitride semiconductor device 10 (referring to FIG. 8), when a portion of the first passivation layer 61 is removed by etching, a portion on the side of the upper surface of the portion of the covering portion 54 located under the gate opening 61A is also removed. As such, the thickness T4 of the part 54A1 of the upper part 54A of the covering portion 54 located under the gate electrode 24 can also be partially reduced.

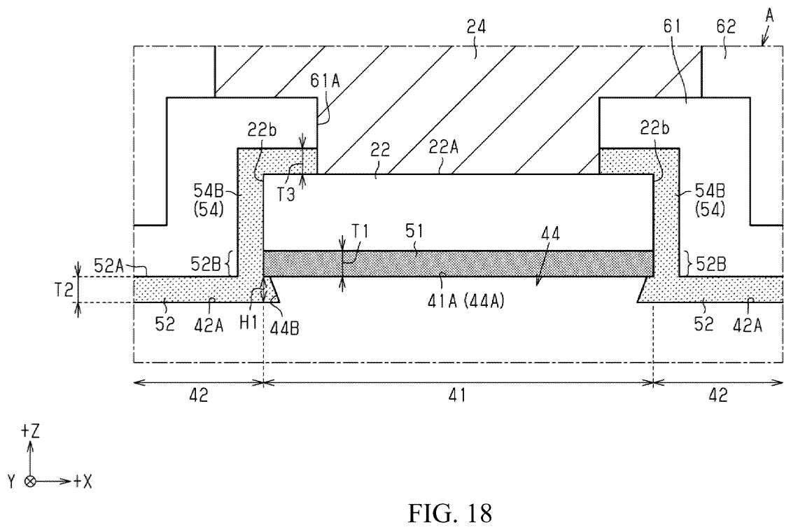

Moreover, in the step of forming the gate opening 61A (referring to FIG. 8), when a portion of the first passivation layer 61 is removed by etching, a portion of the covering portion 54 located below the gate opening 61A can also be completely removed. In this case, as shown in FIG. 18, the gate electrode 24 is in contact with the gate layer 22 through the gate opening 61A.
The electron supply layer 18 can also be configured to omit the covering portion 54. In this case, the gate electrode 24 is in contact with the gate layer 22 through the gate opening 61A.
In the embodiment, the nitride semiconductor device 10 is configured as a nitride semiconductor HEMT but is not limited to being a nitride semiconductor HEMT, and can also be configured as a nitride semiconductor diode.

The term such as “on” used in the present disclosure also includes meanings of both “over” and “above”, unless otherwise specified in the context. Thus, the expression “a first layer formed on a second layer” can refer to that the first layer is directly disposed on the second layer to be in contact with the second layer in one embodiment, as well as that the first layer is disposed above the second layer without being in contact with the second layer in another embodiment. That is to say, the term “on” does not eliminate a structure having another layer formed between the first layer and the second layer.

The Z direction used in the present disclosure is not necessarily a vertical direction, and is not necessarily completely consistent with the vertical direction. Thus, in various structures associated with the present disclosure, “up/top” and “down/bottom” of the Z direction described herein are not limited to “up” and “down” of the vertical direction. For example, the X direction can be the vertical direction, or the Y direction can be the vertical direction.

The terms “first”, “second” and “third” of the present disclosure are for distinguishing targets, and are not intended for ranking the targets.

### NOTE

The technical ideas that can be understood from the present disclosure are described below. Note that, for the purpose of aiding understanding and not for the purpose of limitation, the components described in the appendices are given the reference signs of the corresponding components in the embodiments. The reference signs are shown as examples to aid understanding, and the components described in each appendix should not be limited to the components indicated by the reference signs.

### Note 1

A nitride semiconductor device (10), comprising:
an electron travelling layer (16), made of a nitride semiconductor;
an electron supply layer (18), formed on the electron travelling layer (16) and made of a nitride semiconductor having a band gap larger than a band gap of the electron travelling layer (16);
a gate layer (22), formed on a portion of the electron supply layer (18) and made of a nitride semiconductor including acceptor-type impurities;
a gate electrode (24), formed on the gate layer (22);
a passivation layer (26), covering the electron supply layer (18), the gate layer (22) and the gate electrode (24), and having a source opening (26A) and a drain opening (26B) separated from the source opening (26A), wherein the gate layer (22) is interposed between the source opening (26A) and the drain opening (26B);
a source electrode (28), in contact with the electron supply layer (18) through the source opening (26A); and
a drain electrode (30), in contact with the electron supply layer (18) through the drain opening (26B), wherein
the electron travelling layer (16) includes:
   a first portion (41), located under the gate layer (22); and
   a second portion (42), located between the gate layer (22) and the source opening (26A), and located between the gate layer (22) and the drain opening (26B) in a plan view,
the electron supply layer (18) includes:
   a first electron supply layer (51), formed on the first portion (41) and located below the gate layer (22); and
   a second electron supply layer (52), formed on the second portion (42) and connected to the first electron supply layer (51).

### Note 2

The nitride semiconductor device (10) of Note 1, wherein an interface (18A) is formed between the first electron supply layer (51) and the second electron supply layer (52).

### Note 3

The nitride semiconductor device (10) of Note 1 or 2, wherein
the electron supply layer (18) includes a covering portion (54) covering an upper surface (22A) and side surfaces (22B) of the gate layer (22), and connected to the second electron supply layer (52), and
a part (54A) of the covering portion (54) covering the upper surface (22A) of the gate layer (22) is sandwiched between the gate layer (22) and the gate electrode (24).

### Note 4

The nitride semiconductor device (10) of any one of Notes 1 to 3, wherein
the first portion (41) of the electron travelling layer (16) has a protrusion (44) protruding over the second portion (42), and
the first electron supply layer (51) of the electron supply layer (18) is formed on the protrusion (44).

### Note 5

The nitride semiconductor device (10) of Note 4, wherein
along a direction in which the gate layer (22) is arranged between the source electrode (28) and the drain electrode (30), a width (W1) of the protrusion (44) of the first portion (41) is substantially less than a width (W2) of the gate layer (22).

### Note 6

The nitride semiconductor device (10) of Note 4 or 5, wherein
along a thickness direction, an upper surface (52A) of the second electron supply layer (52) is located at same position as an upper surface (44A) of the protrusion (44) or lower than the upper surface (44A) of the protrusion (44), and
the second electron supply layer (52) covers a side surface (44B) of the protrusion (44) and includes a connecting portion (52B) connected to the first electron supply layer (51).

### Note 7

The nitride semiconductor device (10) of Note 4 or 5, wherein
along a thickness direction, an upper surface (52A) of the second electron supply layer (52) is located higher than an upper surface (44A) of the protrusion (44).

### Note 8

The nitride semiconductor device (10) of any one of Notes 1 to 3, wherein an upper surface (42A) of the second portion (42) of the electron travelling layer (16) is coplanar with an upper surface (41A) of the first portion (41) of the electron travelling layer (16).

### Note 9

The nitride semiconductor device (10) of any one of Notes 1 to 8, wherein a thickness (T2) of the second electron supply layer (52) is same as a thickness (T1) of the first electron supply layer (51).

### Note 10

The nitride semiconductor device (10) of any one of Notes 1 to 9, wherein the passivation layer (26) includes:
a first passivation layer (61), covering the second electron supply layer (52); and
a second passivation layer (62), covering the first passivation layer (61) and the gate electrode (24).

### Note 11

The nitride semiconductor device (10) of any one of Notes 1 to 10, wherein
the electron travelling layer (16) is GaN layer,
the electron supply layer (18) is AlGaN layer, and
the gate layer (22) is GaN layer including acceptor-type impurities.

### Note 12

A method of manufacturing a nitride semiconductor device (10), comprising:
forming an initially formed electron supply layer (70) on an electron travelling layer (16) made of a nitride semiconductor;
forming a gate layer (22) made of a nitride semiconductor including acceptor-type impurities on the initially formed electron supply layer (70);
removing a portion of the initially formed electron supply layer (70) by etching to expose the electron travelling layer (16) while leaving a portion under the gate layer (22), thereby forming a first electron supply layer (51) which is a remaining portion of the initially formed electron supply layer (70);
forming a re-formed electron supply layer (73) connected to the first electron supply layer (51) on the electron travelling layer (16) exposed by etching;
forming a passivation layer (26, 61, 62) on the re-formed electron supply layer (73);
forming a gate electrode (24) over the gate layer (22); and
forming a source electrode (28) and a drain electrode (30) on the re-formed electron supply layer (73), wherein
the initially formed electron supply layer (70) and the re-formed electron supply layer (73) are made of a nitride semiconductor having a band gap larger than a band gap of the electron travelling layer (16).

### Note 13

The method of Note 12, wherein
the re-formed electron supply layer (73) is formed to include a covering portion (54) covering an upper surface (22A) and side surfaces (22B) of the gate layer (22), and
the gate electrode (24) is formed on a portion (54A) of the covering portion (54) covering the upper surface (22A) of the gate layer (22).

### Note 14

The method of Note 12 or 13, wherein when the portion of the initially formed electron supply layer (70) is removed by etching, a portion of an upper side surface of the electron travelling layer (16) is also removed.

### Note 15

The method of any one of Notes 12 to 14, wherein
the forming of the gate electrode (24) on the gate layer (22) includes:
   forming a metal layer (74) on the gate layer (22); and
   removing a portion of the metal layer (74) by etching to form the gate electrode (24) which is a remaining portion of the metal layer (74), and
the forming of the passivation layer (26, 61, 62) on the re-formed electron supply layer (73) includes:
   forming a first passivation layer (61) on the re-formed electron supply layer (73) before forming the metal layer (74) and after forming the gate electrode (24); and
   forming a second passivation layer (62) on the first passivation layer (61).

1. A nitride semiconductor device, comprising:
an electron travelling layer, made of a nitride semiconductor;
an electron supply layer, formed on the electron travelling layer and made of a nitride semiconductor having a band gap larger than a band gap of the electron travelling layer;
a gate layer, formed on a portion of the electron supply layer and made of a nitride semiconductor including acceptor-type impurities;
a gate electrode, formed on the gate layer;
a passivation layer, covering the electron supply layer, the gate layer and the gate electrode, and having a source opening and a drain opening separated from the source opening, wherein the gate layer is interposed between the source opening and the drain opening;
a source electrode, in contact with the electron supply layer through the source opening; and
a drain electrode, in contact with the electron supply layer through the drain opening, wherein
the electron travelling layer includes:
a first portion, located under the gate layer; and
a second portion, located between the gate layer and the source opening, and located between the gate layer and the drain opening in a plan view,
the electron supply layer includes:
a first electron supply layer, formed on the first portion and located below the gate layer; and
a second electron supply layer, formed on the second portion and connected to the first electron supply layer.

2. The nitride semiconductor device of claim 1, wherein
the electron supply layer includes a covering portion covering an upper surface and side surfaces of the gate layer, and connected to the second electron supply layer, and
a part of the covering portion covering the upper surface of the gate layer is sandwiched between the gate layer and the gate electrode.

3. The nitride semiconductor device of claim 1, wherein
the first portion of the electron travelling layer has a protrusion protruding over the second portion, and
the first electron supply layer of the electron supply layer is formed on the protrusion.

4. The nitride semiconductor device of claim 3, wherein
along a direction in which the gate layer is arranged between the source electrode and the drain electrode, a width of the protrusion of the first portion is substantially less than a width of the gate layer.

5. The nitride semiconductor device of claim 3, wherein
along a thickness direction, an upper surface of the second electron supply layer is located at same position as an upper surface of the protrusion or lower than the upper surface of the protrusion, and
the second electron supply layer covers a side surface of the protrusion and includes a connecting portion connected to the first electron supply layer.

6. The nitride semiconductor device of claim 3, wherein
along a thickness direction, an upper surface of the second electron supply layer is located higher than an upper surface of the protrusion.

7. The nitride semiconductor device of claim 1, wherein an upper surface of the second portion of the electron travelling layer is coplanar with an upper surface of the first portion of the electron travelling layer.

8. The nitride semiconductor device of claim 1, wherein a thickness of the second electron supply layer is same as a thickness of the first electron supply layer.

9. The nitride semiconductor device of claim 1, wherein the passivation layer includes:
a first passivation layer, covering the second electron supply layer; and
a second passivation layer, covering the first passivation layer and the gate electrode.

10. The nitride semiconductor device of claim 1, wherein
the electron travelling layer is GaN layer,
the electron supply layer is AlGaN layer, and
the gate layer is GaN layer including acceptor-type impurities.

11. The nitride semiconductor device of claim 2, wherein
the electron travelling layer is GaN layer,
the electron supply layer is AlGaN layer, and
the gate layer is GaN layer including acceptor-type impurities.

12. The nitride semiconductor device of claim 3, wherein
the electron travelling layer is GaN layer,
the electron supply layer is AlGaN layer, and
the gate layer is GaN layer including acceptor-type impurities.

13. The nitride semiconductor device of claim 4, wherein
the electron travelling layer is GaN layer,
the electron supply layer is AlGaN layer, and
the gate layer is GaN layer including acceptor-type impurities.

14. The nitride semiconductor device of claim 5, wherein
the electron travelling layer is GaN layer,
the electron supply layer is AlGaN layer, and
the gate layer is GaN layer including acceptor-type impurities.

15. The nitride semiconductor device of claim 6, wherein
the electron travelling layer is GaN layer,
the electron supply layer is AlGaN layer, and
the gate layer is GaN layer including acceptor-type impurities.

16. The nitride semiconductor device of claim 7, wherein
the electron travelling layer is GaN layer,
the electron supply layer is AlGaN layer, and
the gate layer is GaN layer including acceptor-type impurities.

17. The nitride semiconductor device of claim 8, wherein
the electron travelling layer is GaN layer,
the electron supply layer is AlGaN layer, and
the gate layer is GaN layer including acceptor-type impurities.

18. A method of manufacturing a nitride semiconductor device, comprising:
forming an initially formed electron supply layer on an electron travelling layer made of a nitride semiconductor;
forming a gate layer made of a nitride semiconductor including acceptor-type impurities on the initially formed electron supply layer;
removing a portion of the initially formed electron supply layer by etching to expose the electron travelling layer while leaving a portion under the gate layer, thereby forming a first electron supply layer which is a remaining portion of the initially formed electron supply layer;
forming a re-formed electron supply layer connected to the first electron supply layer on the electron travelling layer exposed by etching;
forming a passivation layer on the re-formed electron supply layer;
forming a gate electrode over the gate layer; and
forming a source electrode and a drain electrode on the re-formed electron supply layer, wherein
the initially formed electron supply layer and the re-formed electron supply layer are made of a nitride semiconductor having a band gap larger than a band gap of the electron travelling layer.

19. The method of claim 18, wherein
the re-formed electron supply layer is formed to include a covering portion covering an upper surface and side surfaces of the gate layer, and
the gate electrode is formed on a portion of the covering portion covering the upper surface of the gate layer.

20. The method of claim 18, wherein when the portion of the initially formed electron supply layer is removed by etching, a portion of an upper side surface of the electron travelling layer is also removed.
